(19) United States
(12) Patent Application Publication
(10) Pub. No.: US 2011/0250831 A1
(43) Pub. Date: Oct. 13, 2011

(54) AIR-CONDITIONING SYSTEM AND AIR CONDITIONER THEREOF

(75) Inventors: Zhao-Wei Huang, Taoyuan Hsien (TW); Yung-Hung Tsou, Taoyuan Hsien (TW)

(73) Assignee: DELTA ELECTRONICS, INC., Taoyuan Hsien (TW)

(21) Appl. No.: 13/049,621

(22) Filed: Mar. 16, 2011

(30) Foreign Application Priority Data
Apr. 7, 2010 (TW) 099110746
May 21, 2010 (TW) 099116320

(51) Int. Cl. H05K 5/02

(52) U.S. Cl. 454/184

(57) ABSTRACT

An air-conditioning system is used in a data center. The air-conditioning system includes plural electronic apparatuses, plural air conditioners and plural airflow blocking structures. The plural airflow blocking structures are arranged in airflow paths of respective air conditioners. If one of the plural air conditioners is disabled, the airflow blocking structure of the disabled air conditioner is automatically closed to block a low flow-resistance path and adjust the airflow paths.

### FIELD OF THE INVENTION

The present invention relates to an air-conditioning system and an air conditioner, and more particularly to an air-conditioning system and an air conditioner with an adjustable airflow path.

### BACKGROUND OF THE INVENTION

With rapid development of computer and network technologies, various computer servers such as web servers, print servers and database servers are installed in many enterprises or institutions for providing dedicated functionality. For example, a great number of computer servers are installed in a large-sized telecommunication service provider for complying with the requirements of storing, transmitting and managing data in order to increase the reliability of the telecommunication service. For maintaining and managing these computer servers, they are usually installed with a computer data center or a telecommunication data center.

As known, the serves of the computer data center or the telecommunication data center are continuously operated all the day. Since the computer servers are disposed within a close space of the data center, a substantial amount of heat is generated during operations of the computer servers. If the heat is not effectively dissipated away, the performance of the computer servers will be deteriorated. For efficient operation of the computer servers, the data center is equipped with plural air conditioners to provide a controlled environment. Since the computer servers are continuously operated, these air conditioners should be continuously turned on to maintain or reduce the temperature of the data center. As known, the continuous operations of the air conditioners consume a great deal of electricity and are not cost-effective. In this situation, the air conditioners have shortened use lives. In a case that an air conditioner is disabled (e.g. in a standby status or a maintaining status, or breakdown), the original airflow path is usually altered and thus the overall heat-dissipating efficiency is deteriorated.

FIG. 1 is a schematic view illustrating an air-conditioning system of a data center according to the prior art. As shown in FIG. 1, the air-conditioning system 10 is housed in the data center 1. The air-conditioning system 10 includes plural electronic apparatuses 11 and plural air conditioners 12. The electronic apparatuses 11 are for example computers, servers, network devices, or the like. The electronic apparatuses 11 and the air conditioners 12 are disposed on a floor 13 of the data center 1. The floor 13 has several hollow portions such that airflow is allowed to flow through or circulate through the hollow portions.

As shown in FIG. 1, the electronic apparatuses 11 are arranged in the middle area of the data center 1, and the air conditioners 12 are arranged at bilateral sides of the data center 1 for providing cooling airflow to cool the electronic apparatuses 11. In a case that the air conditioners 12 are normally operated, the airflow path is in the direction A. That is, the down-blowing cooled airflows are produced by the air conditioners 12, then transported through the space 140 between the floor 13 and the bottom surface 14 of the data center 1, and penetrated through the hollow portions of the floor 13 to blow the electronic apparatuses 11. When the cooled airflows pass through the electronic apparatuses 11, the heat generated from the electronic apparatuses 11 will be partially removed and thus heated airflows are exhausted from the electronic apparatuses 11. The heated airflows are moved upwardly, circulated and then inhaled into the air conditioners 12 to be cooled. In such manner, a circulated airflow path is formed within the data center 1.

FIG. 2 is a schematic view illustrating the airflow path of the air-conditioning system as shown in FIG. 1, in which a short-circulating problem occurs. In a case that the air conditioner 120 is disabled (in a standby status or a maintaining status, or breakdown), the original airflow path is altered into a low flow-resistance path. That is, a portion of cooled airflow outputted from the air conditioners 121 and 122 is possibly introduced into the air conditioner 120 through the airflow outlet 120a (in the direction B), then exhausted out of the airflow inlet 120b, and finally introduced into the air conditioners 121 and 122. As such, a low flow-resistance path occurs. Since the normal airflow path C is diverged and a portion of cooled airflow B passes through the low flow-resistance path, a short-circulating problem occurs. The occurrence of the short-circulating problem will reduce the amount of the cooled airflows to reach the electronic apparatuses 11 because a portion of cooled airflow B will be returned back to the air conditioners 121 and 122 through the low flow-resistance path. In other words, if the short-circulating problem occurs, the cooling efficacy of the air conditioners 121 and 122 will be deteriorated.

FIG. 3 is a schematic view illustrating a conventional air conditioner. As shown in FIG. 3, the air conditioner 12 includes a casing 12a and plural airflow supply units 123, 124, 125 and 126. The airflow supply units 123, 124, 125 and 126 are disposed within the casing 12a and arranged in a stacked form. The airflow supply unit 123 has an airflow inlet 123a, an airflow outlet 123b and a channel 123c in communication with the airflow inlet 123a and the airflow outlet 123b. The airflow supply unit 124 has an airflow inlet 124a, an airflow outlet 124b and a channel 124c in communication with the airflow inlet 124a and the airflow outlet 124b. The airflow supply unit 125 has an airflow inlet 125a, an airflow outlet 125b and a channel 125c in communication with the airflow inlet 125a and the airflow outlet 125b. The airflow supply unit 126 has an airflow inlet 126a, an airflow outlet 126b and a channel 126c in communication with the airflow inlet 126a and the airflow outlet 126b. Generally, airflows D1, D2, D3 and D4 are respectively introduced into the airflow supply units 123, 124, 125 and 126 through the airflow inlets 123a, 124a, 125a and 126a. Then, the airflows D1, D2, D3 and D4 pass through the channels 123c, 124c, 125c, 126c to partially remove heat. Afterwards, the cooled airflows D1, D2, D3 and D4 are respectively exhausted out of the air conditioner 12 through the airflow outlets 123b, 124b, 125b and 126b to cool the electronic apparatuses 11.

The conventional air conditioner 12, however, still has some drawbacks. For example, in a case that one of the airflow supply units is disabled (in a standby status or a maintaining status, or breakdown), the original airflow path is altered into a low flow-resistance path. In this situation, a short-circulating problem occurs. For example, as shown in FIG. 4, the airflow supply unit 124 is disabled. As such, a portion E1 of the cooled airflow D1 outputted from the airflow supply unit 123 and a portion E2 of the cooled airflow D3 outputted from the airflow supply unit 125 may be introduced into the airflow supply unit 124 through the airflow outlet 124b, then pass through the channel 124c, and finally exhausted out of the airflow inlet 124a. Since the airflow supply unit 124 is disabled, the cooled airflows D1 and D3 are diverged, and the portions E1 and E2 pass through the low flow-resistance path. The occurrence of the short-circulating problem will reduce the amount of the cooled airflows D1 and D3 to reach the electronic apparatuses 11. In other words, if the short-circulating problem occurs, the cooling efficacy of the airflow supply units 123 and 125 will be deteriorated.

FIG. 5 is a schematic view illustrating the airflow path of another conventional air conditioner, in which a short-circulating problem occurs. As shown in FIG. 5, the air conditioner 15 is a down-blowing air conditioner. The down-blowing air conditioner 15 includes a casing 15a and plural air supply units 150 and 151. The air supply units 150 and 151 are disposed within the casing 15a. The air supply units 150 and 151 are arranged beside each other horizontally. The airflow supply unit 150 has an airflow inlet 150a, an airflow outlet 150b and a channel 150c in communication with the airflow inlet 150a and the airflow outlet 150b. The airflow supply unit 151 has an airflow inlet 151a, an airflow outlet 151b and a channel 151c in communication with the airflow inlet 151a and the airflow outlet 151b. Generally, airflows are respectively introduced into the airflow supply units 150 and 151 through the airflow inlets 150a and 150b, and then pass through the channels 150c and 151c to partially remove heat. Afterwards, the cooled airflows are respectively exhausted out of the air conditioner 15 through the airflow outlets 150b and 151b. Since the airflow outlets 150 and 151 face downwardly, the down-blowing cooled airflows are produced.

Similarly, in a case that one of the airflow supply units is disabled (in a standby status or a maintaining status, or breakdown), the original airflow path is altered into a low flow-resistance path. In this situation, a short-circulating problem occurs. For example, as shown in FIG. 5, the airflow supply unit 151 is disabled. As such, a portion G of the cooled airflow F outputted from the airflow supply unit 150 may be introduced into the airflow supply unit 151 through the airflow outlet 151b, then pass through the channel 151c, and finally exhausted out of the airflow inlet 151a. Since the airflow supply unit 151 is disabled, the portion G of the cooled airflow F may easily flow into the low flow-resistance path. The occurrence of the short-circulating problem will reduce the amount of the cooled airflow F to reach the electronic apparatuses. In other words, if the short-circulating problem occurs, the cooling efficacy of the airflow supply unit 150 and the overall air conditioner 15 will be deteriorated.

Therefore, there is a need of providing an improved air conditioner and an improved air-conditioning system to obviate the drawbacks encountered from the prior art.

### SUMMARY OF THE INVENTION

It is an object of the present invention to provide an air conditioner and air-conditioning system for preventing from occurrence of the short-circulating problem if one of the airflow supply units is disabled, thereby increasing the cooling efficacy.

Another object of the present invention provides an air conditioner and air-conditioning system in order to achieve power-saving and cost-effective purposes.

In accordance with an aspect of the present invention, there is provided an air-conditioning system for use in a data center. The air-conditioning system includes plural electronic apparatuses, plural air conditioners and plural airflow blocking structures. The plural airflow blocking structures are arranged in airflow paths of respective air conditioners. If one of the plural air conditioners is disabled, the airflow blocking structure of the disabled air conditioner is automatically closed to block a low flow-resistance path and adjust the airflow paths.

In accordance with another aspect of the present invention, there is provided an air conditioner of an air-conditioning system. The air conditioner includes a casing and plural airflow supply units. The plural airflow supply units are disposed within the casing. Each airflow supply unit includes an airflow inlet, a fan, an airflow outlet, a channel and an airflow blocking structure. The channel is in communication with the airflow inlet and the airflow outlet. The airflow blocking structure is arranged in an airflow path of the airflow supply unit. If one of the plural airflow supply units is disabled, the airflow blocking structure of the disabled airflow supply unit is automatically closed to hinder a cooled airflow from entering the channel of the disabled airflow supply unit, thereby avoiding short circulation and adjusting the airflow path.

In accordance with another aspect of the present invention, there is provided an air-conditioning system for use in a data center. The air-conditioning system includes plural electronic apparatuses, and plural air conditioners for removing heat generated by the electronic apparatuses. Each air conditioner comprises a casing, and plural airflow supply units disposed within the casing. Each airflow supply unit comprises an airflow inlet, a fan, an airflow outlet, a channel in communication with the airflow inlet and the airflow outlet, and an airflow blocking structure arranged in an airflow path of the airflow supply unit. If one of the airflow supply units is disabled, the airflow blocking structure of the disabled airflow supply unit is automatically closed to hinder a cooled airflow from entering the channel of the disabled airflow supply unit, thereby avoiding short circulation and adjusting the airflow path.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating an air-conditioning system of a data center according to the prior art;

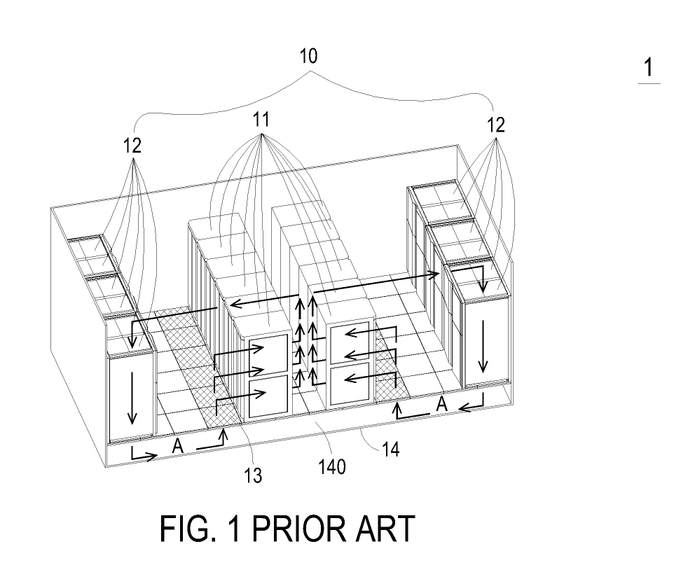

FIG. 2 is a schematic view illustrating the airflow path of the air-conditioning system as shown in FIG. 1, in which a short-circulating problem occurs;

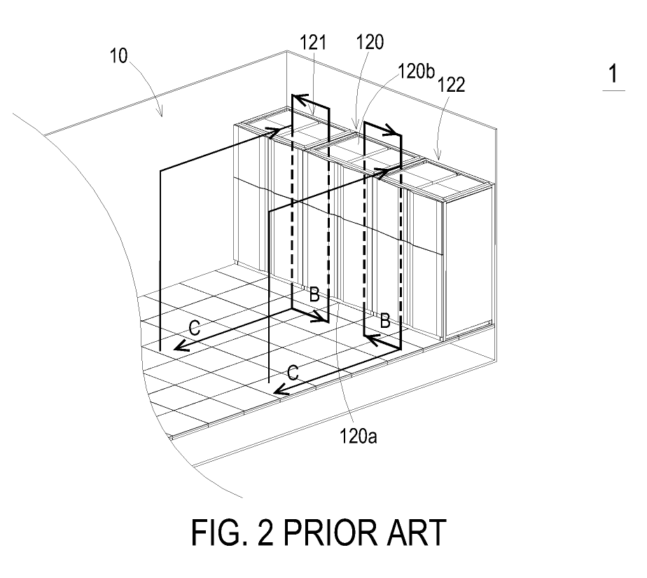

FIG. 3 is a schematic view illustrating a conventional air conditioner;

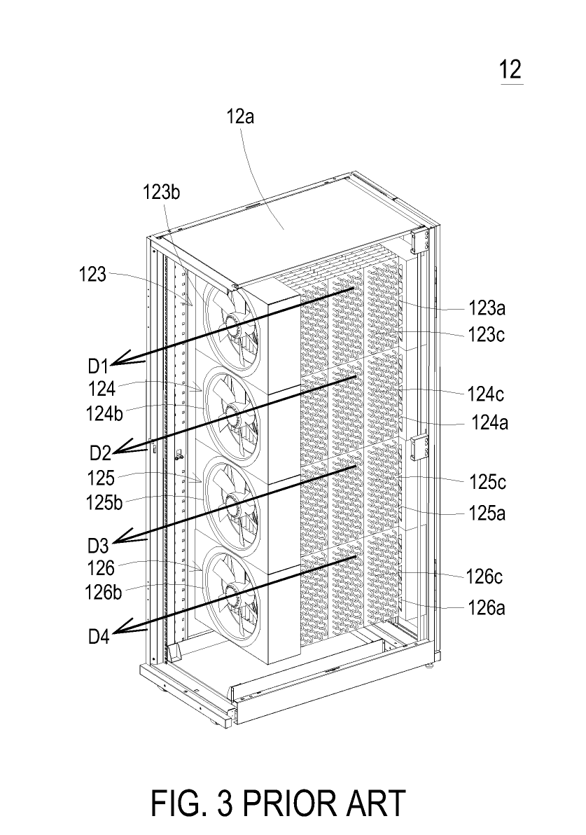

FIG. 4 is a schematic view illustrating the airflow path of the air conditioner as shown in FIG. 3, in which a short-circulating problem occurs;

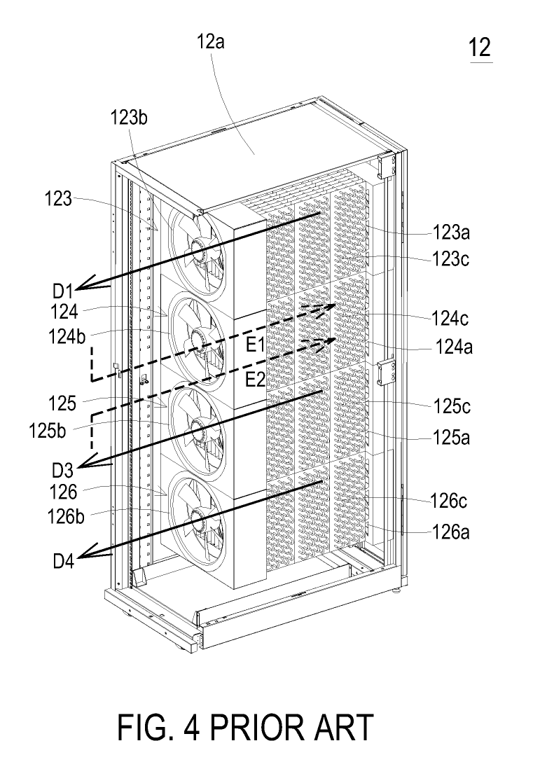

FIG. 5 is a schematic view illustrating the airflow path of another conventional air conditioner, in which a short-circulating problem occurs;

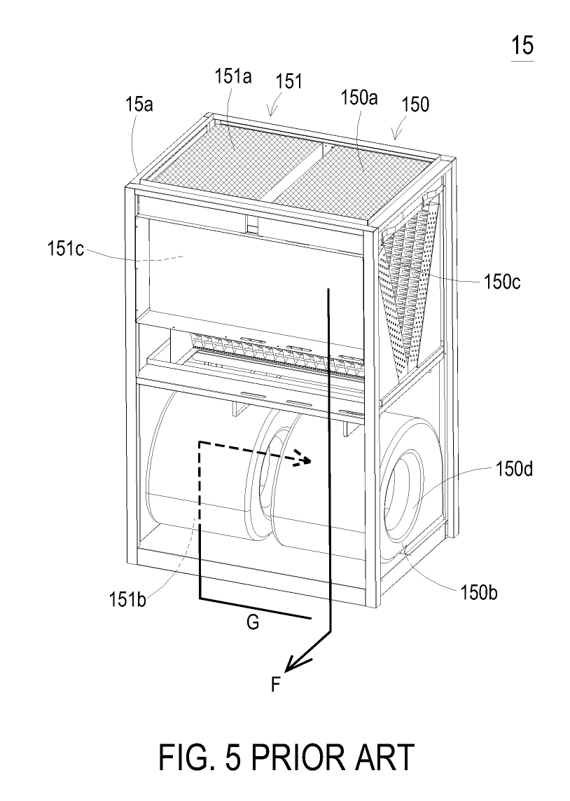

FIG. 6 is a schematic functional block diagram illustrating the architecture of an air-conditioning system according to an embodiment of the present invention;

FIG. 7 is a schematic cutaway view illustrating the air-conditioning system of FIG. 6 disposed within the data center;

FIG. 8 is a schematic view illustrating the air-conditioning system of FIG. 6, in which one of the airflow blocking structures is closed;

FIG. 9 is a schematic view illustrating the airflow path of an air-conditioning system according to another embodiment of the present invention;

FIG. 10 is a schematic view illustrating an air conditioner according to an embodiment of the present invention;

FIG. 11 is a schematic functional block diagram illustrating the architecture of another air-conditioning system of the present invention; and

FIG. 12 is a schematic view illustrating an air conditioner according to another embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

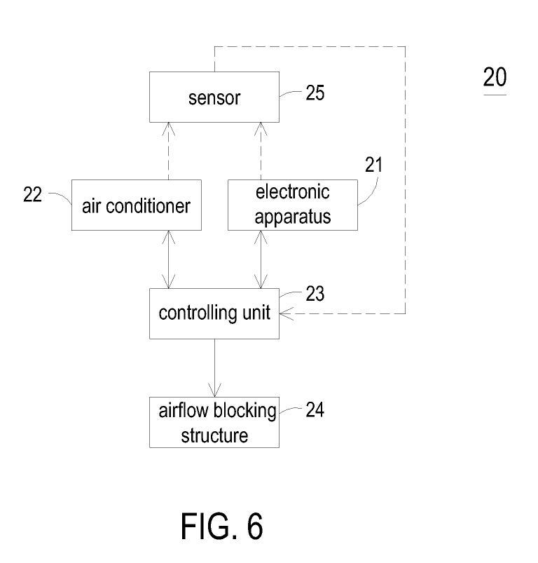

FIG. 6 is a schematic functional block diagram illustrating the architecture of an air-conditioning system according to an embodiment of the present invention. As shown in FIG. 6, the air-conditioning system 20 comprises plural electronic apparatuses 21, plural air conditioners 22 and plural airflow blocking structures 24. An example of the electronic apparatus 21 includes but is not limited to a computer or a server. Since the electronic apparatus 21 is continuously operated, a great deal of heat is generated. The uses of plural air conditioner 22 produce cooled airflow to cool the electronic apparatus 21. The airflow blocking structures 24 are arranged in the airflow paths of respective air conditioner 22. An example of the airflow blocking structure 24 includes but is not limited to an airflow door. Especially, the airflow blocking structure 24 is an airflow door, which may be opened or closed in response to a pushing force generated from the airflow. For example, once the airflow is directed to the airflow blocking structure 24, the pushing force generated from the airflow may cause the airflow blocking structure 24 to be opened along the airflow direction. Once no airflow is directed to the airflow blocking structure 24, the airflow blocking structure 24 is closed.

In some embodiments, the air-conditioning system 20 further includes a controlling unit 23. The controlling unit 23 is connected with the electronic apparatuses 21, the air conditioners 22 and the airflow blocking structures 24 through signal wires. As such, the operations of the electronic apparatuses 21, the air conditioners 22 and the airflow blocking structures 24 are controlled by the controlling unit 23. In a case that one of the air conditioners 22 is disabled, the airflow blocking structures 24 of the disabled air conditioner 22 is closed under control of the controlling unit 23 so that the airflow path is adjusted to block the low flow-resistance path.

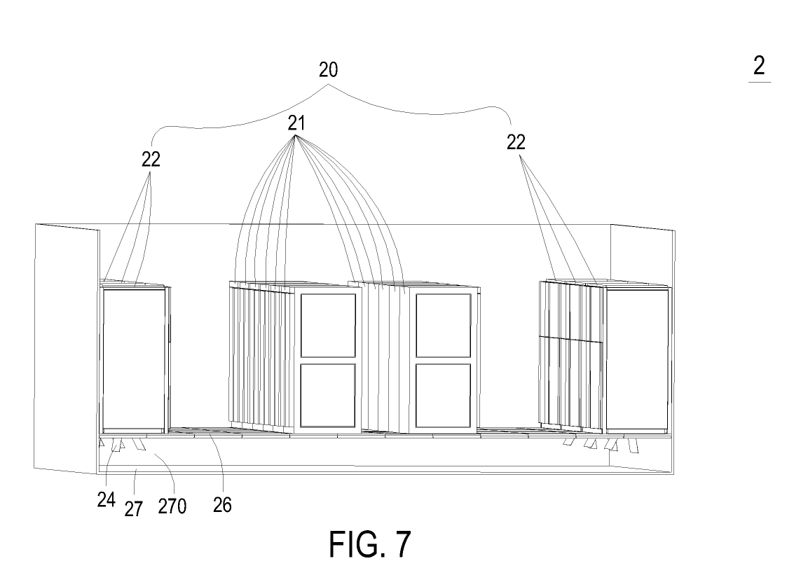

In some embodiments, the air-conditioning system 20 further includes plural sensors 25. The sensors 25 are electrically connected with the electronic apparatuses 21, the air conditioners 22 and the controlling unit 23 for sensing the controlling parameters of the electronic apparatuses 21 and/or the air conditioners 22. The controlling parameters of the electronic apparatuses 21 and/or the air conditioners 22 include for example temperature, humidity, voltage, or the like. Moreover, the sensors 25 may be disposed within a data center 2 (see FIG. 7) for detecting the controlling parameters (e.g. internal temperature, humidity) of the data center 2. The controlling parameters detected by the sensors 25 are transmitted to the controlling unit 23. According to the controlling parameters detected by the sensors 25, the controlling unit 23 may judge whether the airflow blocking structures 24 of the disabled air conditioner 22 is opened or closed.

FIG. 7 is a schematic cutaway view illustrating the air-conditioning system of FIG. 6 disposed within the data center. The air-conditioning system 20 is installed in a data center 2. The air-conditioning system 20 comprises plural electronic apparatuses 21 and plural air conditioners 22. The electronic apparatuses 21 are arranged in the middle area of the data center 2. The air conditioners 22 are arranged at bilateral sides of the data center 2 for providing cooling airflow to cool the electronic apparatuses 21. In addition, the electronic apparatuses 21 and the air conditioners 22 are disposed on a floor 26 of the data center 2. The floor 26 has several hollow portions such that airflow is allowed to flow through or circulate through the hollow portions. That is, the down-blowing cooled airflows are produced by the air conditioners 22, then transported through the space 270 between the floor 26 and the bottom surface 27 of the data center 2, and penetrated through the hollow portions of the floor 26 to blow the electronic apparatuses 21.

In this embodiment, the air conditioners 22 are down-blowing air conditioners. More specially, the airflow blocking structures 24 of the air conditioners 22 are arranged under the floor 26 of the data center 2. When the airflow blocking structures 24 are opened, the cooled airflows exhausted from the air conditioners 22 will flow downwardly through the hollow portions of the floor 26 and the opened airflow blocking structures 24. The cooled airflows are then transported through the space 270 and penetrated through the hollow portions (near the electronic apparatuses 21) of the floor 26 to blow the electronic apparatuses 21.

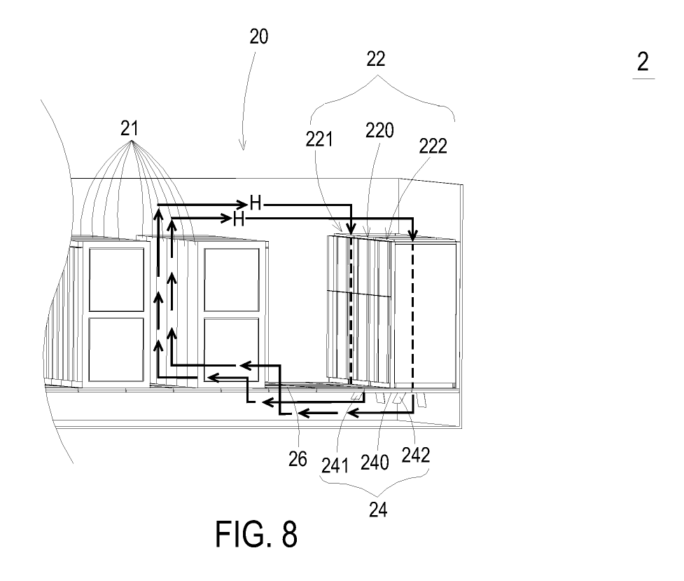

FIG. 8 is a schematic view illustrating the air-conditioning system of FIG. 6, in which one of the airflow blocking structures is closed. In a case that one of the air conditioners 22 is disabled (in a standby status or a maintaining status, or breakdown), the airflow blocking structure 24 of the disabled air conditioner 22 is opened or closed under control of the controlling unit 23 (see FIG. 6). For example, once the air conditioner 220 is disabled, the airflow door 240 under the air conditioner 220 will be closed by the controlling unit 23. Since the airflow blocking structure 24 of the air conditioner 220 is closed, the low flow-resistance path is blocked. Meanwhile, the cooled airflows exhausted from the air conditioners 221 and 222, which are arranged at bilateral sides of the air conditioner 220, will flow downwardly through the hollow portions of the floor 26. Since the airflow blocking structure 24 is closed and the low flow-resistance path is blocked, the cooled airflows exhausted from the air conditioners 221 and 222 will be circulated along the normal path H to blow the electronic apparatus 21. The heated airflows exhausted from the electronic apparatuses 21 are moved upwardly, circulated and then inhaled into the air conditioners 22 to be cooled. In this situation, the cooling efficacy of the air conditioners 22 will be increased and the performance of the air conditioners 22 will not be deteriorated. Moreover, according to the concept of the present invention, the air conditioners 22 may be used as redundant air conditioner 22 in order to prolong the use life.

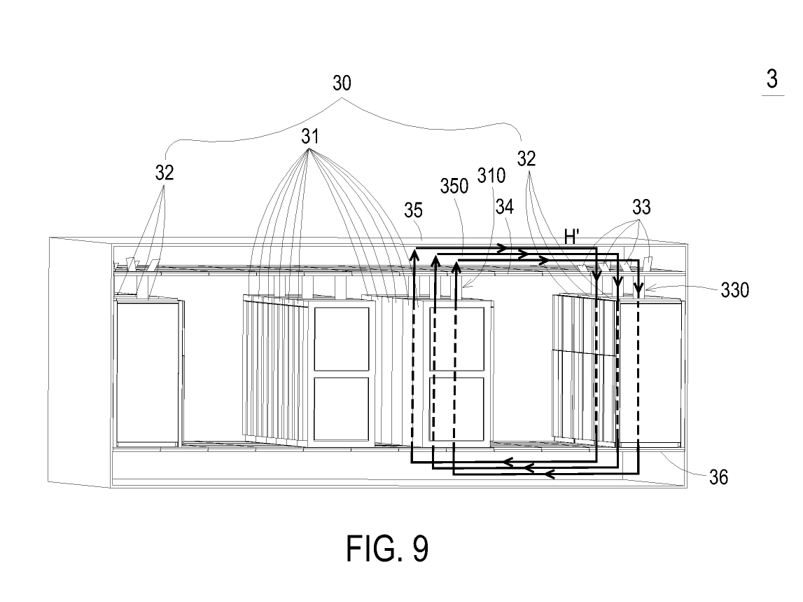

FIG. 9 is a schematic view illustrating the airflow path of an air-conditioning system according to another embodiment of the present invention. The air-conditioning system 30 is installed in a data center 3. The air-conditioning system 30 includes plural electronic apparatuses 31, plural air conditioners 32 and plural airflow blocking structures 33. The configurations of the electronic apparatuses 31, the conditioners 32 and the airflow blocking structures 33 are similar to those illustrated in the above embodiments, and are not redundantly described herein. In this embodiment, the data center 3 further includes a ceiling 34. The ceiling 34 is disposed over the electronic apparatuses 31 and the air conditioners 32. In addition, a space 350 is defined between the ceiling 34 and the top surface 35 of the data center 3. The ceiling 34 has several hollow portions such that airflow is allowed to flow through the hollow portions and transported through the space 350. In this embodiment, the airflow blocking structures 33 are disposed over the ceiling 34 and aligned with corresponding air conditioners 32. In a case that one of the air conditioners 32 is disabled, the airflow blocking structure 34 of the disabled air conditioner 32 is closed under control of the controlling unit (not shown) in order to block the low flow-resistance path. In this embodiment, the airflow blocking structures 33 and the air conditioners 32 are aligned with each other through respective air conduits 330. As such, the airflows are downwardly introduced into the air conditioners 32 through the air conduits 330 and the airflow inlets of the air conditioners 32. In addition, the electronic apparatuses 31 are in communication with the space 350 above the ceiling 34 through air conduits 310. As such, the heated airflows exhausted from the electronic apparatuses 31 may be moved upwardly into the space 350 through the air conduits 310. Then, the heated airflows exhausted from the electronic apparatuses 31 is transported through the space 350, and introduced into the air conditioners 32 through the airflow blocking structures 33, the air conduits 330 and the airflow inlets (along the path H′). Afterwards, the cooled airflows exhausted from the bottom surfaces of the air conditioners 32 flow under the floor 36 and are then transported to the electronic apparatuses 31 to cool the electronic apparatuses 31.

In the above embodiments, the airflow blocking structures 24 are disposed under the floor 26 of the data center 2, and the airflow blocking structures 33 are disposed above the ceiling 34 of the data center 3. The locations of the airflow blocking structures are not restricted as long as they are arranged in the low flow-resistance path.

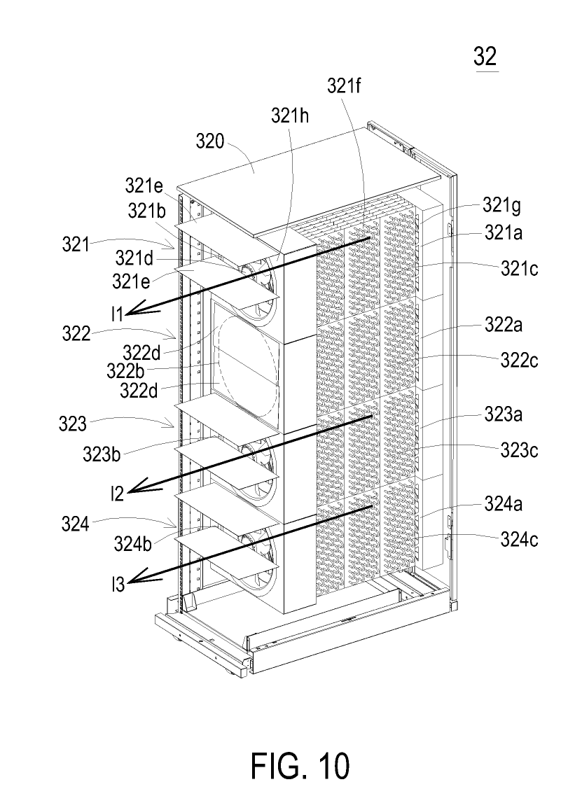

FIG. 10 is a schematic view illustrating an air conditioner according to an embodiment of the present invention. In an embodiment, the air conditioner 32 is installed in a data center. As shown in FIG. 10, the air conditioner 32 includes a casing 320 and plural air supply units 321, 322, 323 and 324. The airflow supply units 321, 322, 323 and 324 are disposed within the casing 320. The configurations of the airflow supply units 321, 322, 323 and 324 are substantially identical. The airflow supply unit 321 has an airflow inlet 321a, an airflow outlet 321b and a channel 321c in communication with the airflow inlet 321a and the airflow outlet 321b. The airflow supply unit 322 has an airflow inlet 322a, an airflow outlet 322b and a channel 322c in communication with the airflow inlet 322a and the airflow outlet 322b. The airflow supply unit 323 has an airflow inlet 323a, an airflow outlet 323b and a channel 323c in communication with the airflow inlet 323a and the airflow outlet 323b. The airflow supply unit 324 has an airflow inlet 324a, an airflow outlet 324b, and a channel 324c in communication with the airflow inlet 324a and the airflow outlet 324b. In this embodiment, the airflow supply units 321, 322, 323 and 324 are lateral-blowing airflow supply units, and arranged in a stacked form.

Take the airflow supply unit 321 for example. The airflow supply unit 321 includes the airflow inlet 321a, the airflow outlet 321b, the channel 321c, a fan 321d and an airflow blocking structure 321e. The airflow inlet 321a is disposed in a first surface 321g of the air supply unit 321. The airflow outlet 321b is disposed in a second surface 321h of the air supply unit 321. The second surface 321h and the first surface 321g are opposed to each other. The fan 321d is arranged between the airflow inlet 321a and the airflow outlet 321b for inhaling the airflow through the airflow inlet 321a, guiding the airflow through the channel 321c and the fan 321d, and exhausting the airflow from the airflow outlet 321b. The airflow blocking structure 321e is arranged in the airflow path of the airflow supply unit 321. For example, the airflow blocking structure 321e is arranged on the second surface 321h of the airflow supply unit 321 and aligned with the airflow outlet 321b. In this embodiment, the airflow blocking structure 321e is a two-blade airflow door. When the two blades of the airflow door are rotated downwardly, the airflow door is closed to completely shelter the airflow outlet 321b in the second surface 321h of the airflow supply unit 321. As such, the short-circulating airflow path is blocked.

In some embodiments, the airflow supply unit 321 further includes a cooling member 321f (e.g. an evaporator). The cooling member 321f is arranged between the airflow inlet 321a and the fan 321d. In addition, the channel 321c may be disposed within the cooling member 321f. As such, the airflow is introduced into the channel 321c through the airflow inlet 321a, cooled by the cooling member 321f, inhaled by the fan 321d, and exhausted through the airflow outlet 321b, thereby producing a cooled airflow I1.

Please refer to FIG. 10 again. In a case that the airflow supply unit 322 of the air conditioner 32 is normally operated, the airflow transported through the channel 322c to the airflow outlet 322b may result in a pushing force to open the airflow blocking structure 322d along the airflow direction. Whereas, in a case that the airflow supply unit 322 is disabled (in a standby status or a maintaining status, or breakdown), no airflow is generated by the airflow supply unit 322. Due to the gravity force, the airflow blocking structure 322d is rotated downwardly to be in the closed status. As such, the possible low flow-resistance path is blocked. By closing the airflow blocking structure 322d, the airflow outlet 322b of the airflow supply unit 32 is closed, and thus the occurrence of the possible low flow-resistance path is eliminated. Since the low flow-resistance path is blocked, the cooled airflows I1, I2 and I3 exhausted out of the airflow supply units 321, 323 and 324 will be circulated along the normal path while increasing the cooling efficacy. In addition, the cooled airflow I1, I2 and I3 exhausted out of the airflow supply units 321, 323 and 324 will be no longer diverged to the low flow-resistance path so that the short-circulating problem is avoided. In this situation, the performance of the airflow supply units 321, 323 and 324 and the air conditioner 32 will not be deteriorated. Moreover, according to the concept of the present invention, one or more of the airflow supply units 321, 322, 323 and 324 may be used as redundant airflow supply units in order to prolong the use life of the overall air conditioner 32.

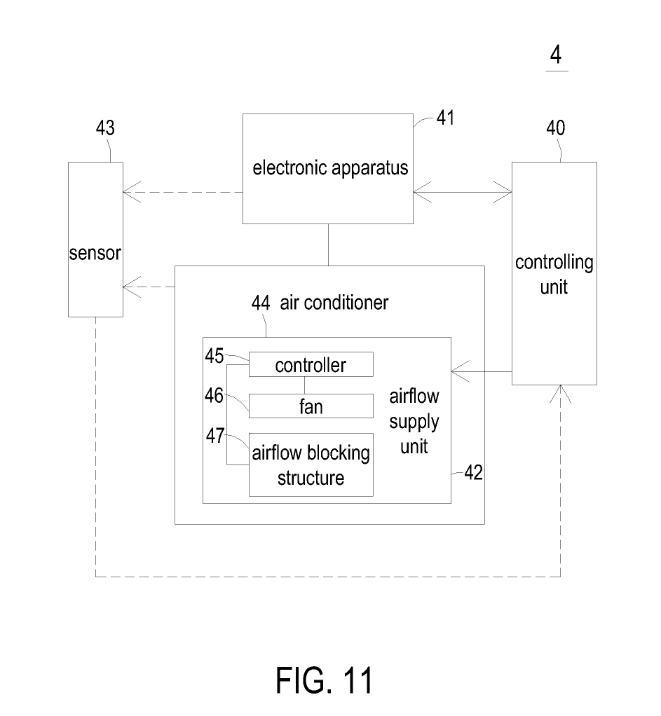

FIG. 11 is a schematic functional block diagram illustrating the architecture of another air-conditioning system of the present invention. As shown in FIG. 11, the air-conditioning system 4 includes a controlling unit 40, at least one electronic apparatus 41 and at least one air conditioner 42. The numbers of the electronic apparatus 41 and the air conditioner 42 may be varied according to the practical requirements. An example of the electronic apparatus 41 includes but is not limited to a computer or a server. Since the electronic apparatus 41 is continuously operated all the day, a great deal of heat is generated. The uses of plural air conditioners 42 produce cooled airflow to cool the electronic apparatus 41. The air conditioner 42 includes plural airflow supply units 44. For clarification, only an airflow supply unit 44 is shown in the drawing. Each of the airflow supply units 44 includes a controller 45, a fan 46 and an airflow blocking structure 47. The controller 45 is electrically connected to the fan 46 and the airflow blocking structure 47 for controlling on/off status of the fan 46 and open/close status of the airflow blocking structure 47. As above mentioned, the airflow blocking structure 47 is arranged in the airflow path of the airflow supply unit 44 (e.g. in the airflow outlet of the airflow supply unit 44) for adjusting the airflow path.

Please refer to FIG. 11 again. The controlling unit 40 is connected with the electronic apparatus 41 and the air conditioner 42 through signal wires in order for receiving and controlling operations of the electronic apparatus 41 and the air conditioner 42. In a case that one of the airflow supply units 44 of the air conditioner 42 is disabled, the airflow blocking structure 47 of the disabled airflow supply unit 44 is closed under control of the controlling unit 40 so that the airflow path is adjusted to block the low flow-resistance path. In some embodiments, the air-conditioning system 4 further includes plural sensors 43. The sensors 43 are electrically connected with the electronic apparatus 41, the air conditioner 42 and the controlling unit 40 for sensing the controlling parameters of the electronic apparatus 41 and/or the air conditioner 42. The controlling parameters of the electronic apparatus 41 and/or the air conditioner 42 include for example temperature, humidity, voltage, or the like. Moreover, the sensors 43 may be disposed within a data center (not shown) for detecting the controlling parameters (e.g. internal temperature, humidity) of the data center. The controlling parameters detected by the sensors 43 are transmitted to the controlling unit 40. According to the controlling parameters detected by the sensors 43, the controlling unit 40 may judge whether the airflow blocking structure 47 of the disabled airflow supply unit 44 is opened or closed.

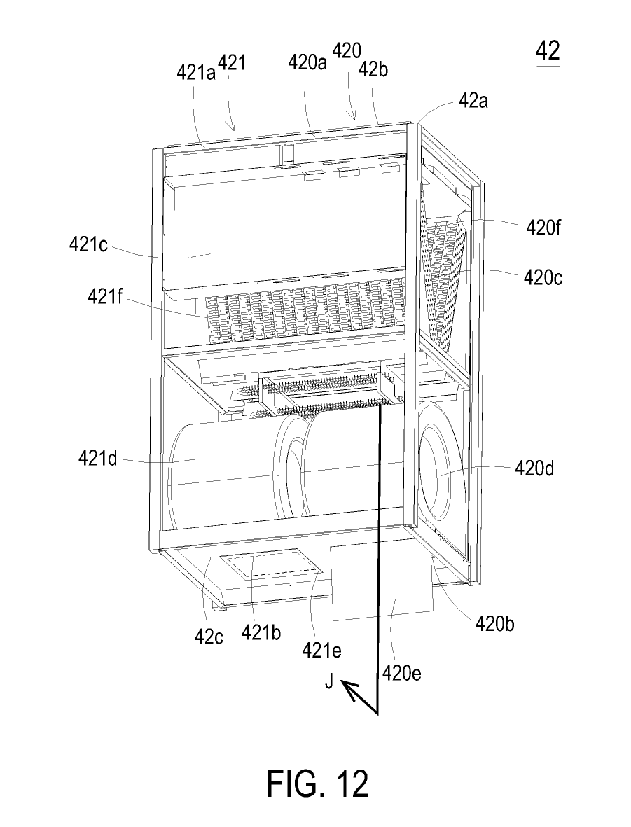

FIG. 12 is a schematic view illustrating an air conditioner according to another embodiment of the present invention. As shown in FIG. 12, the down-blowing air conditioner 42 includes a casing 42a and two air supply units 420 and 421. The air supply units 420 and 421 are disposed within the casing 42a. The configurations of the air supply units 420 and 421 are substantially identical. In this embodiment, the air supply units 420 and 421 are down-blowing air supply units, which are arranged beside each other horizontally. The airflow supply unit 420 has an airflow inlet 420a, an airflow outlet 420b and a channel 420c in communication with the airflow inlet 420a and the airflow outlet 420b. The airflow supply unit 421 has an airflow inlet 421a, an airflow outlet 421b and a channel 421c in communication with the airflow inlet 421a and the airflow outlet 421b.

Please refer to FIG. 12 again. The airflow supply unit 420 includes the airflow inlet 420a, the airflow outlet 420b, the channel 420c, a fan 420d, a cooling member 420f, and airflow blocking structure 420e and a controller (not show). The airflow supply unit 421 includes the airflow inlet 421a, the airflow outlet 421b, the channel 421c, a fan 421d, a cooling member 421f, and airflow blocking structure 421e and a controller (not show). The configurations of the airflow inlets 420a, 421a, the airflow outlets 420b, 421b, the channels 420c, 421c, the cooling members 420f, 421f, the controllers (not show) and the airflow blocking structures 420e, 421e are similar to those illustrated in the above embodiment, except that the fans 420d and 421d are down-blowing centrifugal fans. For example, a cooled airflow J is downwardly exhausted out the airflow supply unit 420. Moreover, the airflow inlet 420a of the airflow supply unit 420 and the airflow inlet 421a of the airflow supply unit 421 are both arranged in the third surface 42b (top surface) of the casing 42a. The airflow outlets 420b, 421b and the airflow blocking structures 420e, 421e are arranged in the fourth surface 42c (bottom surface) of the casing 42a. The fourth surface 42c and the third surface 42b are opposed to each other. However, those skilled in the art will readily observe that numerous modifications and alterations of the airflow inlets 420a, 421a, the airflow outlets 420b, 421b and the airflow blocking structures 420e, 421e may be made while retaining the teachings of the invention.

Please refer to FIG. 12 again. In a case that one of the airflow supply units 420 and 421 of the air conditioner 42 is disabled (in a standby status or a maintaining status, or breakdown), the airflow blocking structure 420e or 421e is selectively opened or closed under control of the controlling unit 40 of the air-conditioning system 4 (see FIG. 11) or the controller 45 of the air conditioner 42. For example, if the airflow supply unit 421 is disabled, the airflow blocking structure 421e at the bottom of the airflow supply unit 421 will be closed under control of the controlling unit 40 or the controller 45. By closing the airflow blocking structure 421e, the low flow-resistance path that is possibly generated at the bottom of the airflow supply unit 421 is blocked. In this situation, the short-circulating airflow path is also blocked. Since the low flow-resistance path is blocked, the cooled airflow J exhausted out of the adjacent airflow supply unit 420 will be circulated along the normal path while increasing the cooling efficacy. In this situation, the performance of the air conditioner 42 will not be deteriorated. Moreover, according to the concept of the present invention, the airflow supply units 420 and 421 may be used as redundant airflow supply units in order to prolong the use life of the overall air conditioner 42.

From the above description, the air conditioner and the air-conditioning system of the present invention are capable of preventing from occurrence of the short-circulating problem when one of the air conditioners or one of the airflow supply units is disabled, thereby increasing the cooling efficacy. In a case that one of the airflow supply units is disabled, the airflow blocking structure of the disabled airflow supply unit is closed under control of the controlling unit of the air-conditioning system or the controller of the disabled airflow supply unit. By closing the airflow blocking structure, the low flow-resistance path is blocked, and thus the cooled airflow exhausted out of the adjacent airflow supply unit fails to be introduced into the low flow-resistance path. In other words, the performance of the air-conditioning system and the airflow supply units could be maintained. As a consequence, the uses of the air conditioner and the air-conditioning system of the present invention are power-saving and cost-effective and have long use lives.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An air-conditioning system for use in a data center, said air-conditioning system comprising:
plural electronic apparatuses;
plural air conditioners; and
plural airflow blocking structures arranged in airflow paths of respective air conditioners,
wherein if one of said plural air conditioners is disabled, said airflow blocking structure of said disabled air conditioner is automatically closed to block a low flow-resistance path and adjust said airflow paths.

2. The air-conditioning system according to claim 1, wherein said airflow blocking structures are airflow doors.

3. The air-conditioning system according to claim 1, further comprising a controlling unit, which is connected to said electronic apparatuses, said air conditioners and said airflow blocking structures for controlling open/close status of said airflow blocking structures.

4. The air-conditioning system according to claim 3, further comprising plural sensors, which are connected to said air conditioners, said electronic apparatuses and said controlling unit for sensing a controlling parameter of said air conditioners and said electronic apparatuses and transmitting said controlling parameter to said controlling unit.

5. The air-conditioning system according to claim 4, wherein said controlling parameter includes at least one of temperature, humidity and voltage.

6. The air-conditioning system according to claim 1, wherein said airflow blocking structure is arranged at either an airflow inlet or an airflow outlet of a corresponding air conditioner and said air conditioner comprises at least one airflow supply unit, wherein if said airflow supply unit is normally operated, said airflow blocking structure is opened, wherein if said airflow supply unit is disabled, said airflow blocking structure is closed, thereby completely sheltering said airflow inlet or said airflow outlet and blocking a short-circulating airflow path.

7. The air-conditioning system according to claim 1, wherein said plural air conditioners are arranged over a floor of said data center, and said airflow blocking structure of each said air conditioner is arranged under said floor.

8. The air-conditioning system according to claim 1, wherein said plural air conditioners are arranged below a ceiling of said data center, and said airflow blocking structure of each said air conditioner is arranged over said ceiling.

9. An air conditioner of an air-conditioning system, said air conditioner comprising:
a casing; and
plural airflow supply units disposed within said casing, wherein each airflow supply unit comprises:
an airflow inlet;
a fan;
an airflow outlet;
a channel in communication with said airflow inlet and said airflow outlet; and
an airflow blocking structure arranged in an airflow path of said airflow supply unit,
wherein if one of said plural airflow supply units is disabled, said airflow blocking structure of said disabled airflow supply unit is automatically closed to hinder a cooled airflow from entering said channel of said disabled airflow supply unit, thereby avoiding short circulation and adjusting said airflow path.

10. The air conditioner according to claim 9, wherein said plural airflow supply units are lateral-blowing air supply units, which are arranged in a stacked form.

11. The air conditioner according to claim 10, wherein said airflow blocking structure and said airflow outlet of each airflow supply unit are aligned with each other, wherein if said airflow supply unit is normally operated, said airflow blocking structure is opened upwardly in response to a pushing force resulted from said cooled airflow, wherein if said airflow supply unit is disabled, said airflow blocking structure is closed downwardly in response to gravity force of said airflow blocking structure, thereby completely sheltering said airflow outlet and blocking a short-circulating airflow path.

12. The air conditioner according to claim 10, wherein each of said airflow supply units comprises a first surface and a second surface opposed to each other, wherein said airflow inlet is disposed in said first surface, said airflow outlet and said airflow blocking structure are disposed in said second surface.

13. The air conditioner according to claim 9, wherein said plural airflow supply units are down-blowing air supply units, which are arranged beside each other horizontally.

14. The air conditioner according to claim 13, wherein said airflow supply unit further comprises a controller for controlling open/close statuses of said airflow blocking structure.

15. The air conditioner according to claim 14, wherein said airflow blocking structure is arranged at said airflow outlet of said airflow supply unit, wherein if said airflow supply unit is normally operated, said airflow blocking structure is controlled by said controller to be in an open status, wherein if said airflow supply unit is disabled, said airflow blocking structure is controlled by said controller to be in a close status, thereby completely sheltering said airflow outlet and blocking a short-circulating airflow path.

16. The air conditioner according to claim 14, wherein said airflow blocking structure is arranged at said airflow inlet of said airflow supply unit, wherein if said airflow supply unit is normally operated, said airflow blocking structure is controlled by said controller to be in an open status, wherein if said airflow supply unit is disabled, said airflow blocking structure is controlled by said controller to be in a close status, thereby completely sheltering said airflow inlet and blocking a short-circulating airflow path.

17. An air-conditioning system for use in a data center, said air-conditioning system comprising:
plural electronic apparatuses; and
plural air conditioners for removing heat generated by said plural electronic apparatuses, wherein each air conditioner comprises:
a casing; and
plural airflow supply units disposed within said casing, wherein each airflow supply unit comprises an airflow inlet, a fan, an airflow outlet, a channel in communication with said airflow inlet and said airflow outlet, and an airflow blocking structure arranged in an airflow path of said airflow supply unit,
wherein if one of said plural airflow supply units is disabled, said airflow blocking structure of said disabled airflow supply unit is automatically closed to hinder a cooled airflow from entering said channel of said disabled airflow supply unit, thereby avoiding short circulation and adjusting said airflow path.

18. The air-conditioning system according to claim 17, further comprising a controlling unit, which is connected to said electronic apparatuses, said air conditioners and said airflow blocking structures for controlling open/close status of said airflow blocking structures.

19. The air-conditioning system according to claim 17, wherein if said airflow supply unit is normally operated, said airflow blocking structure is opened upwardly in response to a pushing force resulted from said cooled airflow, wherein if said airflow supply unit is disabled, said airflow blocking structure is closed downwardly in response to gravity force of said airflow blocking structure.

20. The air-conditioning system according to claim 17, wherein said airflow supply unit further comprises a controller for controlling open/close statuses of said airflow blocking structure, wherein if said airflow supply unit is normally operated, said airflow blocking structure is controlled by said controller to be in an open status, wherein if said airflow supply unit is disabled, said airflow blocking structure is controlled by said controller to be in a close status.
